(19) United States
(12) Patent Application Publication
(10) Pub. No.: US 2002/0102805 A1
(43) Pub. Date: Aug. 1, 2002

(54) Method for forming shallow junction

(76) Inventors: Huang-Chung Cheng, Hsin-Chu City (TW); Cheng-Jer Yang, Tao-Yuan (TW); Ting-Chang Chang, Hsin-Chu City (TW)

Correspondence Address: POWELL, GOLDSTEIN, FRAZER & MURPHY LLP, P.O. BOX 97233, WASHINGTON, DC, 20090-7223, US

(21) Appl. No.: 09/770,549

(22) Filed: Jan. 26, 2001

(51) Int. Cl. H01L 21/331

(52) U.S. Cl. 438/369

(57) ABSTRACT

A method for forming shallow junction, at least includes following steps: provides a substrate; forms a dielectric layer and a conductor layer in sequence on the substrate; removes part of the conductor layer and part of the dielectric layer to form a gate on the substrate; forms a spacer on the sidewall of the gate; forms a poly-silicon-germanium layer on the bare surface of the substrate and the top of the gate; implants numerous ions into the poly-silicon-germanium layer and forms a metal layer on both the poly-silicon-germanium layer and the spacer; performs a thermal process; and removes residual the metal layer. Whereby, the sequences for ions implantation and formation of poly-silicon-germanium layer are exchangeable.

### BACKGROUND OF THE INVENTION

1. Field of the Invention

The proposed invention relates to a method for forming shallow junction, and more particularly to a method simultaneously has advantages of ions implantation method and self-aligned growth method.

2. Description of the Prior Art

Semiconductor device geometries have dramatically decreased in size since such devices were first introduced several decades ago. Since then, integrated circuits have generally followed the two-year/half-size rule (often called “Moore's Law”) which means that the number of devices which will fit on a chip doubles every two years. Today's wafer fabrication plants are routinely producing 0.2 .mu.m and even 0.13 .mu.m features sizes. As device feature sizes become smaller and integration density increases, issues not previously considered crucial by the industry are becoming of greater concern. In particular, devices with increasingly high integration density have features with high (for example, greater than about 3:1 or 4:1) aspect rations.

Increasingly stringent requirements for processes in fabricating these high integration devices are need in order to produce high quality devices, and conventional substrate processing systems are becoming inadequate to meeting these requirements. For example, substrate processing systems must be able to meet the higher demands for forming shallow junctions, which are necessary for high integration devices with shrinking device geometries. With the advent of smaller device geometries, shallow junctions in semiconductors are needed for various applications including, for example, source/drain, channel stop diffusions for shallow trench isolation, etc. Obviously, because shallow junction is formed by doping particles into substrate and then modifying profile of doped particles, it is important to provide uniform dopant distribution in the doped regions and good control of junction depth.

Ion implantation, which is directly and controllable approach, is inadequate in some applications even it is the most popular approach for forming shallow junctions. With these current approaches, the ability to control dopant distribution and junction depth is limited, especially as depth of shallow junction become shallower. With an approach like ion implantation, controlling dopant distribution is made difficult due to the built-up concentration of ions at the surface of the semiconductor material. Also, ion implantation causes damage to the semiconductor surface, and methods for repairing this substrate damage often make it more difficult to control dopant distribution and junction depth. For instance, ions bombarded at relatively high energy levels have a tendency to tunnel or channel through the semiconductor material and cause damage such as point defects. These point defects, which may lead to irregular and nonuniform junction depths, may be fixed by annealing the implanted semiconductor material at high temperatures (greater than about 900° C.). Perform thermal process, especially rapid annealing process, to the implanted semiconductor material, however, may further increase the junction depth beyond that desired. Accordingly, as technology progresses to even smaller geometry devices, an alternative approach that is able to control the dopant uniformity and junction depth in shallow junction is needed.

Another often-seen approach is the use of a barrier layer for controlling distribution, and specially for reducing depth of doped dopants (ions). Whereby, the barrier layer is formed on the semiconductor substrate before dopants are implanted, and then dopants are implanted through the barrier layer into the substrate. Obviously, existence of the barrier layer will decrease energy of dopants that implanted into the substrate, and then thickness of produced shallow junction is decreased. In other words, application of the barrier layer can reduce thickness of doped dopants without proportional reduction of energy of implanted dopants, and then formation of shallow junction will not be limited by practical ability for controlling dopants implantation. Moreover, available materials of the barrier layer at least include metal, polysilicon and amorphous silicon. Certainly, the barrier layer also can be made of dielectric material, which implanted dopants are easy to be trapped, and used as a dopant diffusion source as discussed in prior art U.S. Pat. No. 6,099,647.

Major advantages of metal barrier layer at least includes metal barrier layer and underlying substrate (or top polycide of gate) can form salicide layer during the thermal process for diffusing implanted dopants. That is to say, metal barrier layer can achieve shallow junction and salicide simultaneously. However, one major disadvantage of metal barrier layer is that some metal atoms of metal barrier layer will be beat into substrate (or top polycide of gate) by implanted dopants, and then leakage current of shallow junction will be increased.

On the other hand, when the barrier layer is made of polysilicon or amorphous silicon, major advantages of silicon (poly or amorphous) barrier layer at least includes that it is difficulty to beat atoms of silicon barrier layer into substrate (or top polycide of gate) by implanted dopants, and then leakage current of shallow junction will not be increased. However, one major disadvantage of silicon barrier layer is that silicon barrier layer and underlying substrate (or top polycide of gate) can not automatically form salicide during the thermal process for diffusing implanted dopants. That is to say, silicon barrier layer can not achieve shallow junction and salicide simultaneously, and then some additional processes are necessary to form required metal (silicate) for providing ohm-contact to shallow junction.

In light of the above, improved methods are needed for forming shallow junction, especially when thickness of shallow junction is further reduced as reduction of critical dimension of semiconductor devices. Moreover, to increase both practical value and convenience of improved methods, improved method should not only have advantages of well-known methods but also is not obviously different from well-known methods.

### SUMMARY OF THE INVENTION

A principal object of the present invention is to provide a manufacturable method for forming shallow junction.

Another object of the present invention is to provide a practical method that forms shallow junction and salicide at the same time.

A further object of the present invention is to provide a method that forms shallow junction without increasing leakage current.

In short, the invention relates to a method for forming shallow junction. The invention at least includes following basic steps: provides a substrate; forms a dielectric layer and a conductor layer in sequence on the substrate; removes part of the conductor layer and part of the dielectric layer to form a gate on the substrate; forms a spacer on the sidewall of the gate; forms a poly-silicon-germanium layer on the bare surface of the substrate and the top of the gate; implants numerous ions into the poly-silicon-germanium layer and forms a metal layer on both the poly-silicon-germanium layer and the spacer; and performs a thermal process.

In addition, it should be noted that the sequences for ions implantation and formation of metal layer are exchangeable. The only limitation is poly-silicon-germanium layer should be formed before ions implantation and formation of metal layer

### BRIEF DESCRIPTION OF THE DRAWINGS

In the accompanying drawing forming a material part of this description, there is shown:

FIG. 1 is a table for comparing metal barrier layer and silicon barrier layer; and

FIG. 2A to FIG. 2H are a series of qualitative cross-section illustrations about essential steps of the invention.

### DESCRIPTION OF THE PREFERRED EMBODIMENT

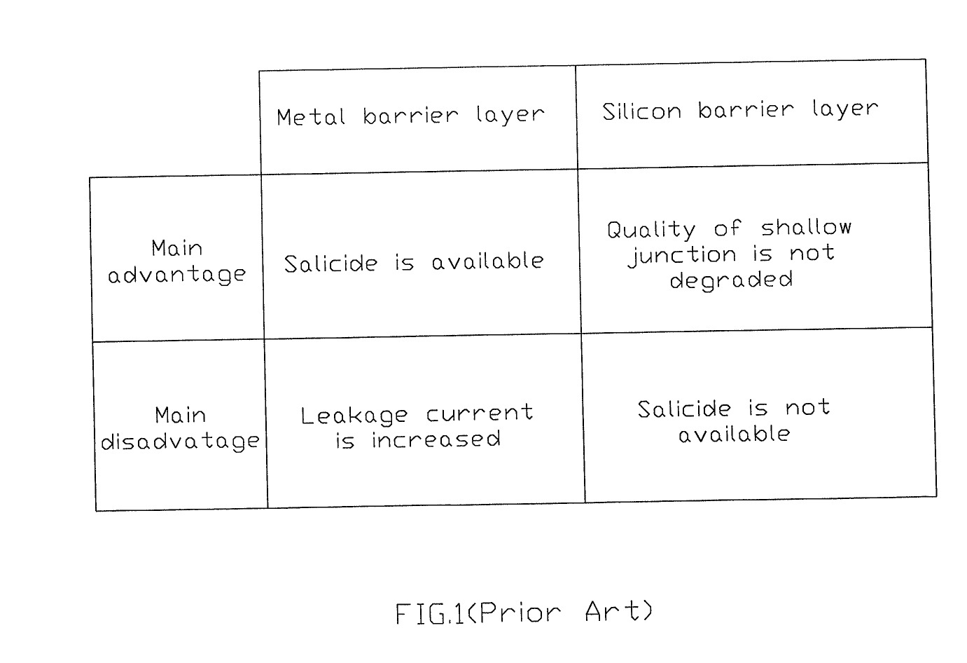

First of all, by referring to FIG. 1, the inventors state that silicon barrier layer is better than metal barrier layer for improving quality of shallow junction, but metal barrier layer is better than silicon barrier layer for it allow formation of salicide. Therefore, an essential way to combine advantages of both metal barrier layer and silicon barrier layer is to search a material which is able to selectively grow on different parts of substrate, but also composited particles of the material essential will not be beat into substrate (or top polycide of gate) by implanted dopants.

In light of the above, the inventor presents a method for forming shallow junction: barrier layer is made of poly-silicon-germanium. In short, as shown in periodic table, germanium and silicon belong to same group (IVA group) and atomic number of germanium (32) is closed to that of silicon (14). Thus, reaction between germanium and implanted ions (dopants) is similar to that between silicon and implanted ions. Thus, just as conventional silicon barrier layer, both structure of substrate and quality of shallow junction are not obviously changed. Moreover, because growing rate of poly-silicon-germanium on silicon is different form growing rate of poly-silicon-germanium on dielectric material, self-aligned function is available.

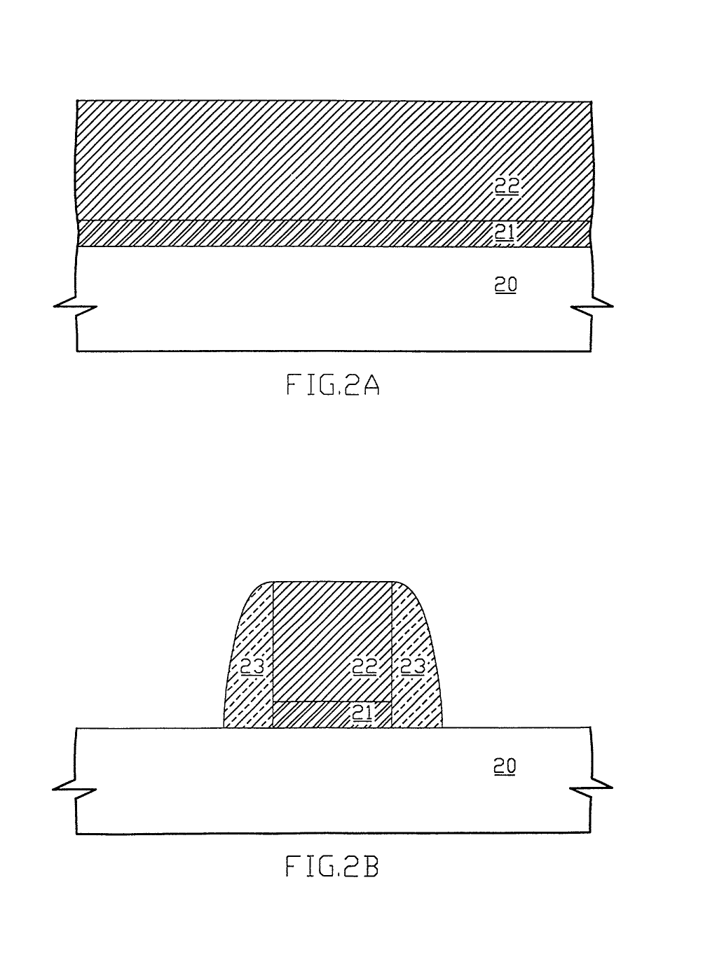

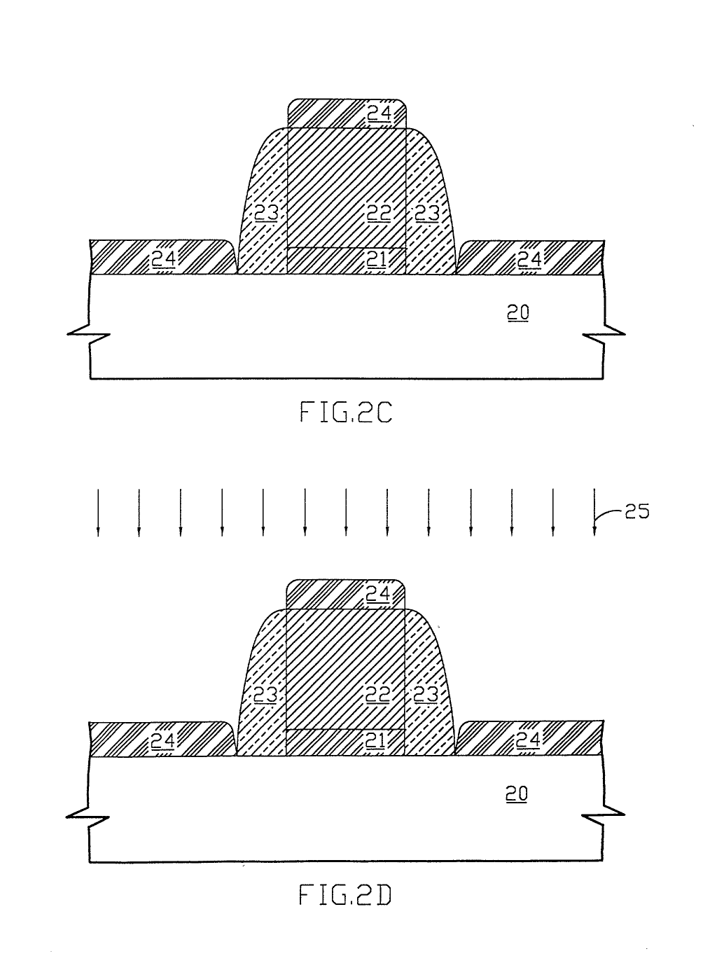

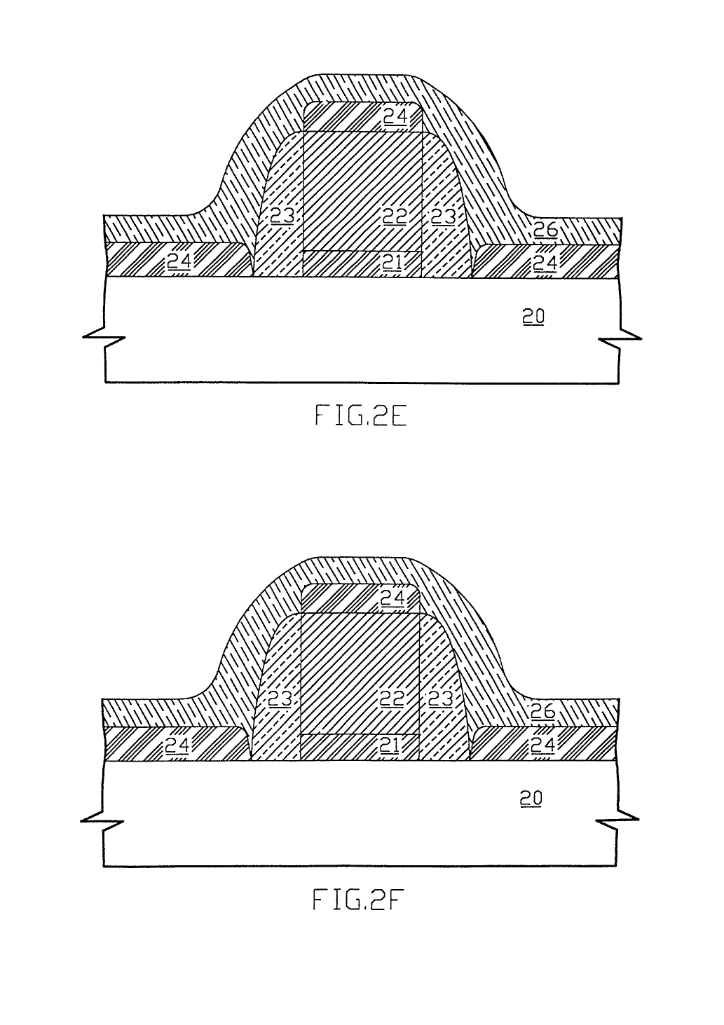

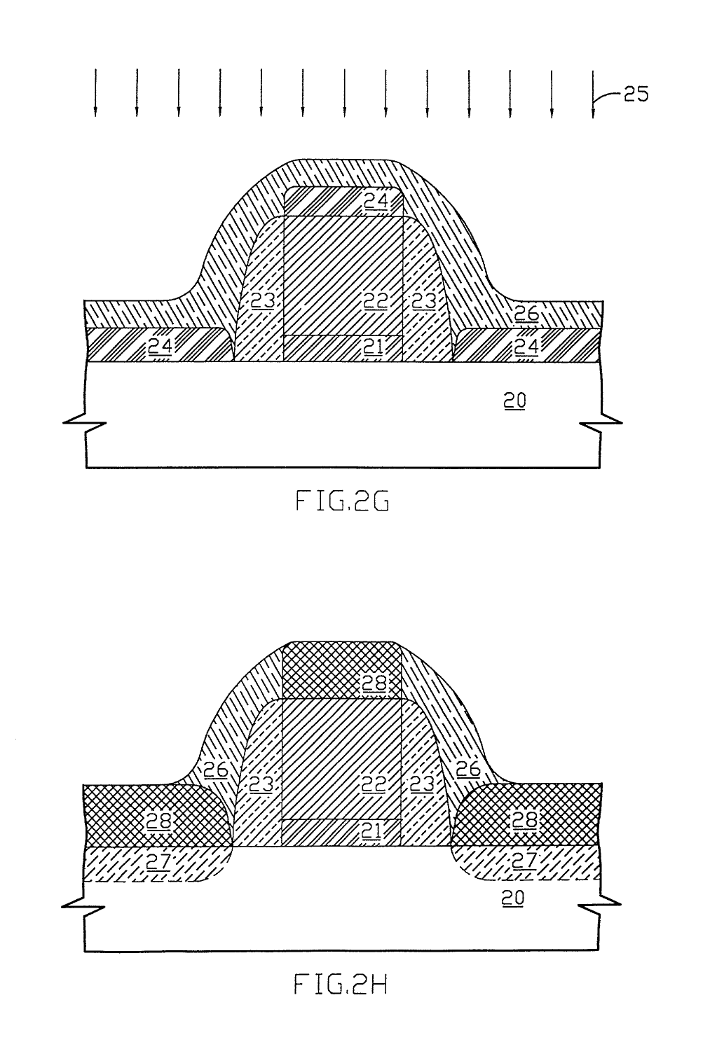

The present invention relates to a method for forming shallow junction. Refers to qualitative cross-section illustrations FIG. 2A through FIG. 2H, the method at least includes following essential steps:

As FIG. 2A shows, provides substrate 20 and then forms dielectric layer 21 and conductor layer 22 in sequence on substrate 20. Herein, further comprises numerous isolations are located in substrate 20. Moreover, available materials of dielectric layer 21 comprise oxide and available materials of conductor layer 22 comprise polycide.

As FIG. 2B shows, removes part of conductor layer 22 and part of dielectric layer 21 to form a gate on substrate 20, and then forms spacer 23 on lateral sidewall of the gate.

As FIG. 2C shows, forms poly-silicon-germanium layer 24 on bare surface of substrate 20 and top of the gate. Herein, the bare surface of substrate 20 is neither not covered by the gate nor occupied by these isolations.

As a matter of face, one important characteristic of poly-silicon-germanium layer 24 is that growing rate of poly-silicon-germanium layer 21 on silicon is larger than growing rate of poly-silicon-germanium layer 24 on dielectric material, especial growing rate on silicon dioxide. Herein, the difference is adjusted and the characteristic can be further understood by analysising nucleation condition of poly-silicon-germanium. Anyway, a direct result is that growing rate of poly-silicon-germanium layer 24 on substrate 20 is larger than growing rate of 24 poly-silicon-germanium layer on spacer 23, and growing rate of poly-silicon-germanium layer 24 on the top of the gate also is larger than growing rate of poly-silicon-germanium layer 24 on spacer 23, and the difference can be obviously increased by modified forming process of poly-silicon-germanium layer 24. In other words, formation of poly-silicon-germanium layer 24 is selective and then distribution of poly-silicon-germanium layer 24, almost only locates on the bare surface of substrate 20 and top of the gate, provides a channel to form shallow junction and salicide at the same time.

In addition, poly-silicon-germanium layer 24 usually is formed by a chemical vapor deposition method. Moreover, available react gases for forming poly-silicon-germanium layer 24 comprise Si₂H₂ and GeH₄, flow rate of said react gases is about from 1 sccm to 2 sccm, forming temperature of poly-silicon-germanium layer 24 is from about 500° C. to about 600° C., and forming pressure of poly-silicon-germanium layer 24 is less than 1 mTorr. Obviously, the reacting temperature is less than reacting temperature of expitaxy method (usually is larger than 1000° C.), and then disadvantage of high temperature damage of expitaxy method is avoidable when advantage of precise location of expitaxy method also is provide by self-aligned function of poly-silicon-germanium layer 24. Certainly, key pint of the invention is not how to form poly-silicon-germanium layer 24 but is what kind of material is used to form poly-silicon-germanium layer 24 that allows salicide and good quality shallow junction can be formed simultaneously without often-seen disadvantages of well known metal barrier layer.

As FIG. 2D and FIG. 2E show, implants numerous ions 25 into poly-silicon-germanium layer 24 and then forms metal layer 26 on both poly-silicon-germanium layer 24 and spacer 23. Herein, ions 25 are used to form doped region such as source and drain, available varieties of ions 25 at least includes boron ions and phosphor ions, and both dense ad energy of ions 25 are dependent on practical configuration of transistor. However, it should be noted that the sequence of both implantation of ions 25 and formation of metal layer 26 is exchangeable, and steps shown in both FIG. 2D and FIG. 2E can be replaced by steps shown in both FIG. 2F and FIG. 2G.

Further, it should be emphasized that poly-silicon-germanium layer 24 is a more effective barrier layer than conventional metal barrier layer. Thus, poly-silicon-germanium layer 24 always can effectively prevent ions are implanted deeply inside substrate 20, and further decrease thickness of shallow junction. Besides, by comparing the steps shown in FIG. 2D and FIG. 2E with the steps shown in FIG. 2F and FIG. 2G, it is obvious that implanted ions 25 are blocked by both poly-silicon-germanium layer 24 and metal layer 26 in the later steps but is only blocked by poly-silicon-germanium layer 24 in the previous steps. Obviously, the steps shown in FIG. 2F and FIG. 2G are more profitable for forming shallow junction, especially for ultra-shallow junction.

As shown in FIG. 2H, performs a thermal process, such as rapid thermal process. Herein, the thermal process not only induces diffusion of implanted ions 25 into form shallow junction 27, it also induces reaction between metal of metal layer 26 and poly-silicon-germanium layer 24 (even substrate 20 or polycide of the gate) to form salicide 28. In other words, shallow junction 27 and salicide 28 are formed simultaneously.

In addition, for some specific cases that gate is covered by dielectric layer, the present invention still is suitable and the only modification is that poly-silicon-germanium layer 24 is not formed on the gate. However, one essential characteristic of the invention, growing rate of poly-silicon-germanium layer 24 is different from that on spacer (and gate in these specific cases) is not affected by it. Moreover, to form transistor, following steps at least includes removes residual metal layer 26, forms additional dielectric layer on both substrate 20 and the gate; forms numerous contact holes in additional dielectric layer; and fills metals into the contact holes.

Finally, it also should be emphasized that even only application of poly-silicon-germanium layer is specifically discussed above, it also should be noted that the claimed invention can be expanded to application of poly-silicon-X layer, where X is an element selected from the group of germanium, Tin and Lead. Further, as discussed above, limitations of poly-silicon-X layer are effectively block implanted ions and allows formation of salicide.

Although specific embodiments have been illustrated and described, it will be obvious to those skilled in the art that various modifications may be made without departing from what is intended to be limited solely by the appended claims.

What is claimed is:

1. A method for forming shallow junction, comprising:
providing a substrate;
forming a dielectric layer and a conductor layer in sequence on said substrate;
removing part of said conductor layer and part of said dielectric layer to form a gate on said substrate;
forming a spacer on the sidewall of said gate;
forming a poly-silicon-germanium layer on the bare surface of said substrate and the top of said gate;
implanting a plurality of ions into said poly-silicon-germanium layer;
forming a metal layer on both said poly-silicon-germanium layer and said spacer; and
performing a thermal process.

2. The method according to claim 1, wherein a plurality of isolations are located in said substrate.

3. The method according to claim 1, wherein the bare surface of said substrate is not covered by said gate.

4. The method according to claim 2, wherein the bare surface of said substrate is not occupied by said isolations.

5. The method according to claim 1, wherein said dielectric layer comprises oxide layer.

6. The method according to claim 1, wherein said conductor layer comprises polycide layer.

7. The method according to claim 1, wherein first growing rate of said poly-silicon-germanium layer on silicon is larger than second growing rate of said poly-silicon-germanium layer on dielectric material.

8. The method according to claim 1, wherein growing rate of said poly-silicon-germanium layer on said substrate is larger than growing rate of said poly-silicon-germanium layer on said spacer.

9. The method according to claim 1, wherein growing rate of said poly-silicon-germanium layer on the top of said gate is larger than growing rate of said poly-silicon-germanium layer on said spacer.

10. The method according to claim 1, wherein said poly-silicon-germanium layer is formed by a chemical vapor deposition method.

11. The method according to claim 1, wherein a plurality of react gases for forming said poly-silicon-germanium layer comprise Si₂H₂ and GeH₄.

12. The method according to claim 11, wherein flow rate of said react gases is about from 1 sccm to 2 sccm.

13. The method according to claim 1, wherein forming temperature of said poly-silicon-germanium layer is from about 500° C. to about 600° C.

14. The method according to claim 1, wherein forming pressure of said poly-silicon-germanium layer is less than 1 mTorr.

15. The method according to claim 1, wherein said thermal process comprises rapid thermal process.

16. A method for forming shallow junction, comprising:
providing a substrate;
forming a dielectric layer and a conductor layer in sequence on said substrate;
removing part of said conductor layer and part of said dielectric layer to form a gate on said substrate;
forming a spacer on the sidewall of said gate;
forming a poly-silicon-germanium layer on the bare surface of said substrate and the top of said gate, wherein said bare surface of said substrate is not covered by said gate;
forming a metal layer on both said poly-silicon-germanium layer and said spacer;
implanting a plurality of ions into said poly-silicon-germanium layer; and
performing a thermal process.

17. The method according to claim 16, wherein growing rate of said poly-silicon-germanium layer on said substrate is larger than growing rate of said poly-silicon-germanium layer on said spacer.

18. The method according to claim 16, wherein growing rate of said poly-silicon-germanium layer on the top of said gate is larger than growing rate of said poly-silicon-germanium layer on said spacer.

19. The method according to claim 16, wherein forming temperature of said poly-silicon germanium layer is form about 500° C. to about 600° C.

20. A method for forming transistor with shallow junction, comprising:
providing a substrate, wherein a plurality of isolation are located inside said substrate;
forming a gate on said substrate;
forming a spacer on said sidewall of said gate;
forming a poly-silicon-X layer on a bare surface of said substrate, wherein X is an element selected from the group of germanium, Tin and Lead, and said bare surface of said substrate being not covered by said gate and also being not occupied by said isolation;
implanting a plurality of ions into said poly-silicon-X layer and forms a metal layer on both said poly-silicon-X layer and said spacer, wherein the sequences for the ions implantation and the formation of poly-silicon-germanium layer are exchangeable;
performing a thermal process
forming a dielectric layer on both said substrate and said gate;
forming a plurality of contact holes in said dielectric layer; and
filling said contact holes by conductor.
